(19) United States
(12) Patent Application Publication
(10) Pub. No.: US 2010/0126418 A1
(43) Pub. Date: May 27, 2010

(54) GAS SHOWER MODULE

(75) Inventors: Ming-Tung CHIANG, Hsinchu City (TW); Jung-Chen Chien, Hsinchu County (TW); Jung-Chen Ho, Hsinchu City (TW); Chih-Yung Huang, Taichung County (TW)

Correspondence Address: RABIN & Berdo, PC, 1101 14TH STREET, NW, SUITE 500, WASHINGTON, DC, 20005, US

(73) Assignee: INDUSTRIAL TECHNOLOGY RESEARCH INSTITUTE, Hsinchu (TW)

(21) Appl. No.: 12/369,990

(22) Filed: Feb. 12, 2009

(30) Foreign Application Priority Data
Nov. 26, 2008 (TW) 097145607

(51) Int. Cl. C23C 16/54

(52) U.S. Cl. 118/715

(57) ABSTRACT

A gas shower module for gas deposition chamber with gas channel is disclosed, which comprises: a distributor with at least one diffusion cell positioned therein along first axial direction and a plurality of inlets respectively connecting to the gas channel and the diffusion cell; and a shower with at least one shower channel positioned therein along second axial direction, gas-inlet passages connected to the diffusion cell and the shower channel, and gas-outlet passages connected to the shower channel and gas deposition chamber; wherein the distributor is connected to the shower so that the diffusion cell will be connected to the shower channel through gas-inlet passages and the first axial direction is not be parallel to the second axial direction.

### FIELD OF THE INVENTION

The present invention relates to a gas shower module, and more particularly, to a gas shower module for gas deposition chamber.

### BACKGROUND OF THE INVENTION

With the advance of chemical vapor deposition (CVD) coating technology, the importance of the gas shower module for uniformly delivering a gas into a process region of a CVD deposition chamber is increasing.

Please refer to FIG. 1, which is a schematic view of a conventional gas shower module. In FIG. 1, there is a carrier 11 configured in a chamber 10 that is used for carrying and heating a substrate 12. Accordingly, there is a gas channel 100 formed inside the chamber at a position corresponding to the substrate 12 while enabling the gas channel 100 to be connected to a gas shower module 13. The gas shower module 13 is conventionally formed as a metal panel having a plurality of holes symmetrically distributed thereon, and is designed for enabling a gas that is being fed into the chamber 10 through the gas channel 100 to be distributed evenly onto the substrate 12.

However, the degree of uniformity resulting from the aforesaid gas shower module is usually not satisfactory, and thus it is common to configure a buffer zone 14 in the chamber 10 at a position between the gas channel 100 and the gas shower module 13, by that the gas being fed into the gas shower module 13 through the gas channel 100 will be directed to the buffer zone 14 whereby the inflowing of the gas can be buffered and stabilized before being fed into the gas shower module 13 for discharging, as another embodiment of the invention shown in FIG. 2.

The use of the aforesaid buffer zone is only suitable for low flow situation, and when it is used in a coating process requiring a high-flow gas, the resulting degree of uniformity is still not satisfactory even though the inflowing gas is distributed by the cooperation of the signal-layered buffer zone and the gas shower module. The reasoning is that: as the intake area of a signal central gas inlet designed in the gas shower module 13 is fixed, there will exist an unavoidable time lag between the gases that exist near the center of the gas shower module 13 and those existing at the outer perimeter when the gases are inflowing at a high speed in high flow situation. As shown in FIG. 3, there will be non-uniform gas concentrations around the center of the substrate 12 which may adversely affect the deposition of the high-flow coating process.

There are already many devices be provided for improving the aforesaid disadvantages. One of which is a gas distribution system disclosed in U.S. Pat. No. 6,921,437. As in the aforesaid gas distribution system, gases will be mixed in the showerhead of the system before they are discharged therefrom so that it is not suitable for discharging gases that are mutually reactive. Moreover, since the gas distribution network formed inside the aforesaid system is very complex that not only it is difficult but also it can be very expensive to fabricate.

Another such device is disclosed in U.S. Pat. No. 6,478,872, which describes a method of delivering gas into reaction chamber and shower head used to deliver gas. Although the aforesaid method and showerhead are quite capable of delivering gases with satisfactory degree of uniformity, its structure is still very complex and can be very expensive to manufacture.

Yet, another such device is disclosed in U.S. Pub. No. 2007/0163440, which is a gas separation type showerhead. Despite the aforesaid showerhead is able to prevent gases from mixing and reacting with each other before it is distributed and can deliver the mixed gas with satisfactory degree of uniformity, its structure is still very complex and can be very expensive to manufacture.

Except for the aforesaid shortcomings, those conventional gas shower module are usually formed as a circular disc, as the one shown in FIG. 4, which might be suitable for coating large-sized substrate.

### SUMMARY OF THE INVENTION

The present invention relates to a gas shower module for gas deposition chamber with gas channel, which comprises: at least a distributor, configured with at least one diffusion cell positioned therein along a first axial direction and a plurality of inlets respectively connecting to the gas channel and the diffusion cell; and a shower, further comprising: at least one shower channel positioned therein along a second axial direction; a plurality of gas-inlet passages, connected to the diffusion cell and the shower channel; and a plurality of gas-outlet passages, connected to the shower channel and the gas deposition chamber; wherein the distributor is connected to the shower for enabling the diffusion cell to communicate with the shower channel through the gas-inlet passages, and the first axial direction is not be parallel to the second axial direction.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a schematic view of a conventional gas shower system.

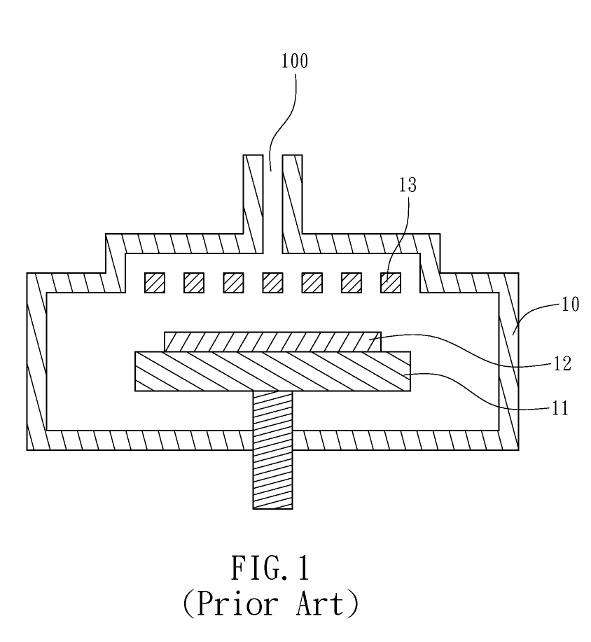

FIG. 2 is a schematic view of another conventional gas shower system.

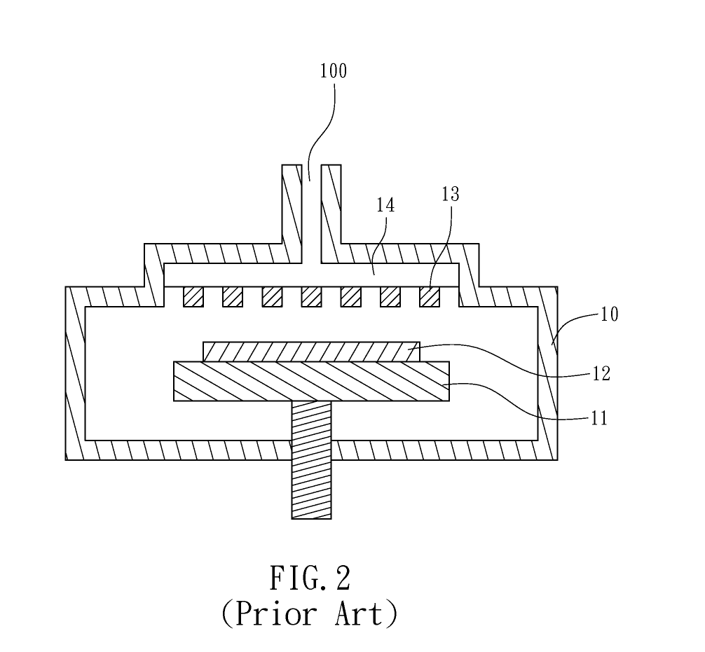

FIG. 3 is a schematic diagram showing gases are non-uniformly concentrated around the center of the substrate by the gas shower system of FIG. 2.

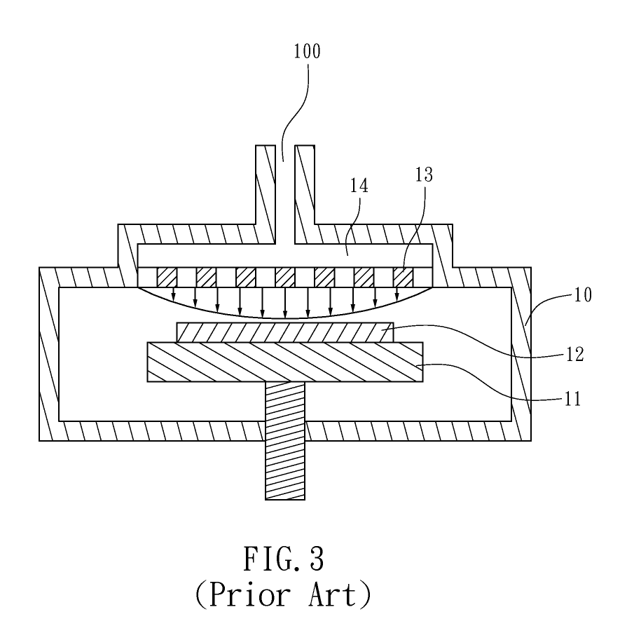

FIG. 4 shows a disc-shaped showerhead used in a conventional gas shower system.

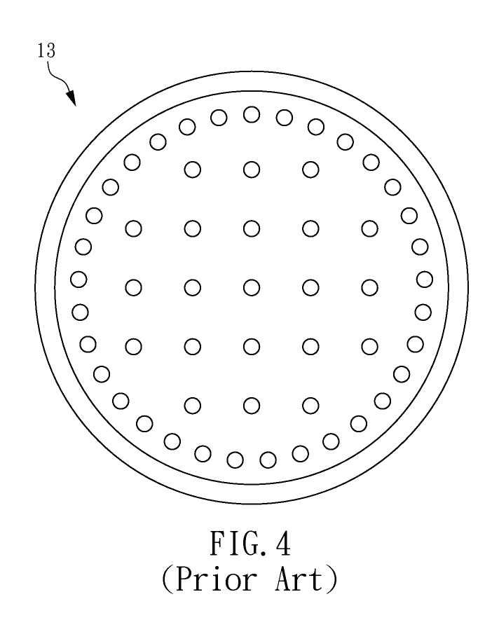

FIG. 5 is a cross sectional view of a gas shower module for gas deposition chamber according to the present invention.

FIG. 6 is a three-dimensional diagram showing a gas shower module according to an embodiment of the invention relating to how its distributor and shower are assembled.

FIG. 7 is a top view of a gas shower module of the invention.

FIG. 8 is a bottom view of a gas shower module of the invention.

FIG. 9 is a three-dimensional diagram showing a gas shower module of the invention without cool blocks.

FIG. 10 is a C-C′ sectional view of FIG. 7.

FIG. 11 is an A-A′ sectional view of FIG. 7.

FIG. 12 is a D-D′ sectional view of FIG. 7.

FIG. 13 is a B-B′ sectional view of FIG. 7.

FIG. 14 is a three-dimensional view of a distributor of the invention as it is viewed from the top thereof.

FIG. 15 is a three-dimensional view of a distributor of the invention as it is viewed from the bottom thereof.

FIG. 16 is a bottom view of a distributor according to an embodiment of the invention.

FIG. 17 is a bottom view of a distributor according to another embodiment of the invention.

FIG. 18 is a top view of a shower of the invention.

FIG. 19 is an X-ray view of a shower of the invention.

FIG. 20 is an X-ray view of a gas shower module of the invention as the distributor and the shower are assembled.

FIG. 21 is a partial enlarged view of FIG. 20.

FIG. 22 is a X-directional pressure distribution diagram of a workpiece in a gas deposition chamber.

FIG. 23 is a Y-directional pressure distribution diagram of a workpiece in a gas deposition chamber.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

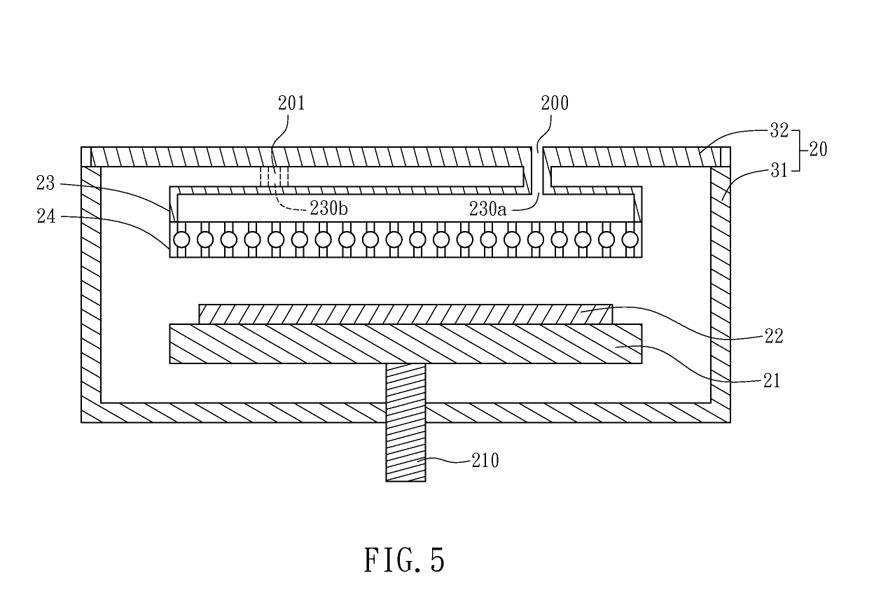

Please refer to FIG. 5, which is a cross sectional view of a gas shower module for gas deposition chamber according to the present invention. As shown in FIG. 5, there is a carrier 21 disposed in a chamber 20 in a manner that one side of the carrier is provided for carrying a substrate 22 for processing and heating while another side of the carrier 21 is connected to a lifting device 210 for adjusting the height of the carrier 21. The chamber 20 is composed of a rectangular-shaped tank 31 and a cap 32, in which there are a distributor 23 and a shower 24 disposed over the substrate 22 while being connected with each other. The distributor is configured with a first inlet 230a and a second inlet 230b in that the first inlet 230a is connected with a gas channel 200 while the second inlet 230b is connected with another gas channel 201. The two gas channels 200, 201 are further connected to intake holes formed on the cap 32 so that a first gas and a second gas can be introduced therefrom is respective without mixing, i.e. there are two different gases being introduced into the system respectively through the two gas channels 200, 201.

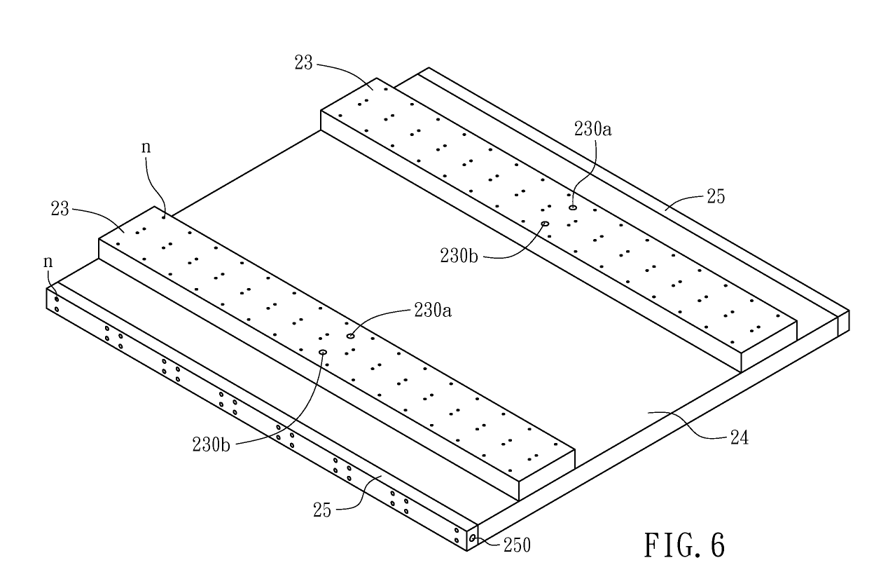

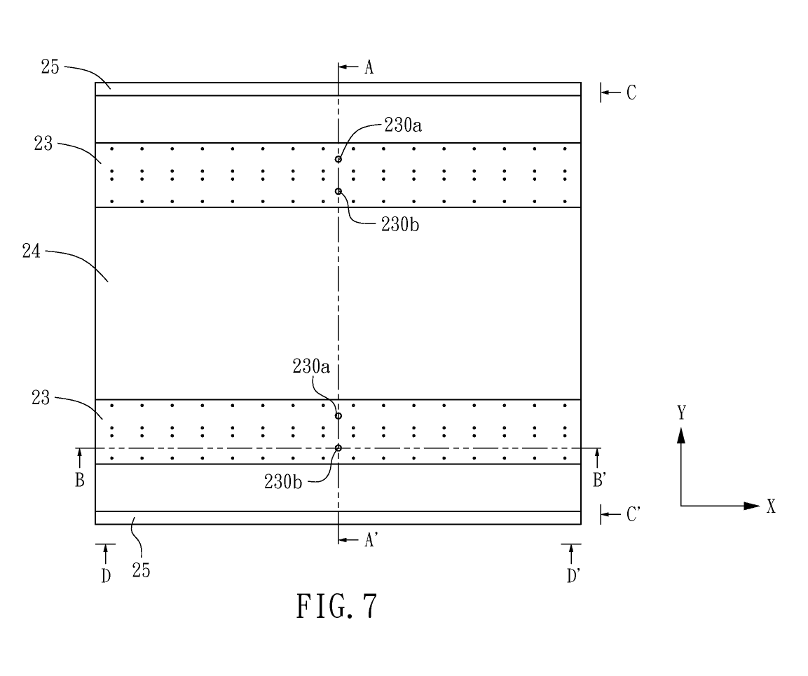

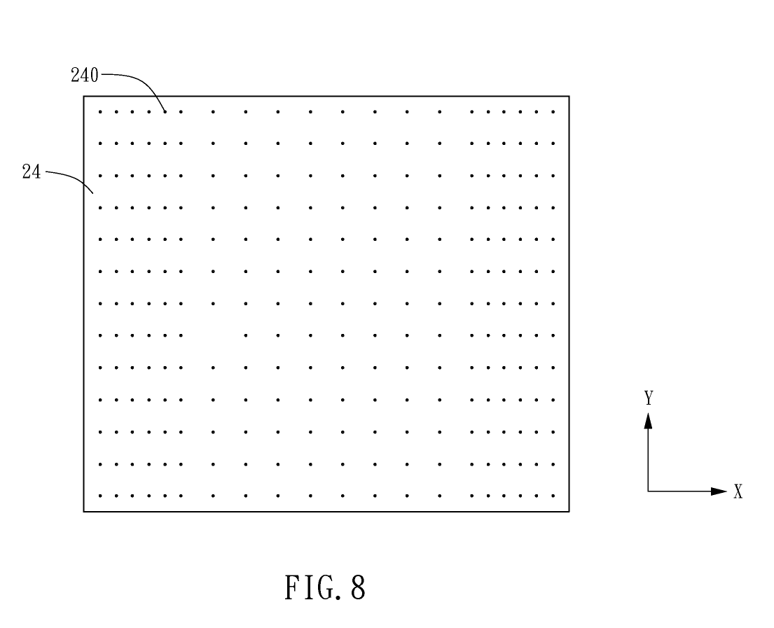

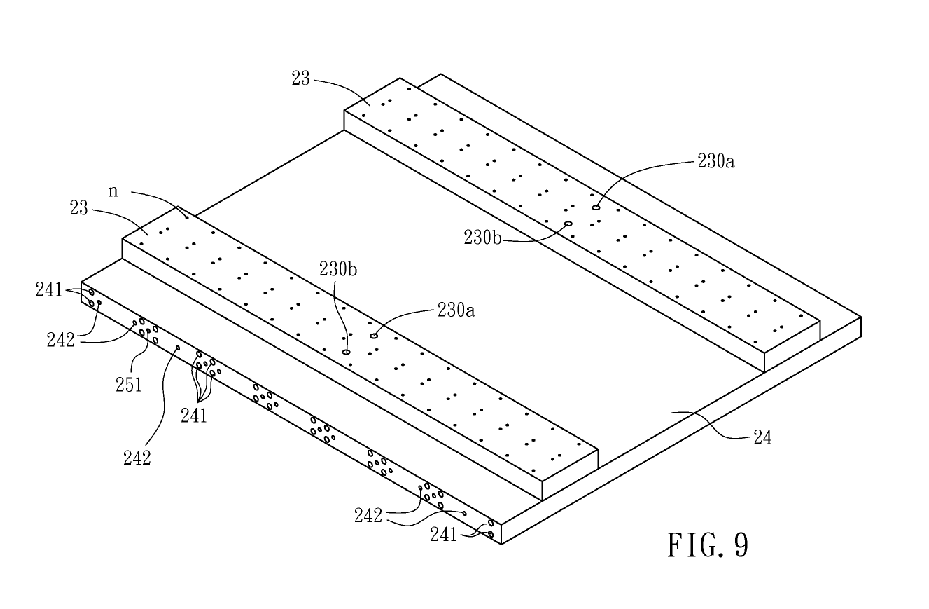

Please refer to FIG. 6, FIG. 7 and FIG. 8, which are respectively a three-dimensional diagram showing a gas shower module according to an embodiment of the invention relating to how its distributor and shower are assembled, and a top view and a bottom view thereof. In this embodiment, the gas shower module is composed of two distributors 23 and a shower 24. Similarly, each distributor 23 is configured with two inlets 230a, 230b while enabling the two inlet 230a, 230b to be connected respectively to two gas channels 200, 201 in a gas deposition chamber. Moreover, there are two cooling blocks 25 being attached respectively to two sides of the shower 24 whereas the each cooling block 25 is formed with a cooling water conduit 250 therein in a manner that one cooling water conduit 250 in one of the two cooling block 25 is selected to be used for allowing cooling water to flow into the system therefrom and thus another cooling water conduit 250 in another cooling block 25 is used for allowing cooling water to flow out of the system therefrom. As shown in FIG. 9, there are a plurality of shower channel 242 and a plurality of cooling passages 251 formed inside the shower 24. Moreover, the two ends of each cooling passage 251 are connected respectively to the two cooling water conduits 250 of the two cooling blocks 25 so that a cooling water flowing in one cooling water conduit 250 of one of the two cooling block 25 can be guided to flow in and out of the shower 24 through the cooling passages 251 and thus into another cooling water conduit 250 of another cooling block 25 where it is discharged. In this embodiment, there are a plurality of screw holes formed at positions surrounding the circumference of the diffusion cell in the distributor 23 for enabling the distributor 23 to be assembled with the shower 24 by screwing screws n into corresponding screw holes. In addition, for achieving air tight, a rubber pad is sandwiched between the distributor 23 and the shower 24. Similarly, as there can are also a plurality of screw holes formed at positions surrounding the circumference of the cooling passages in the each cooling block 25 so that each cooling block 25 can be attached to the shower 24 by screwing, also for achieving air tight, there is a rubber pad being disposed between the cooling block 25 and the shower 24.

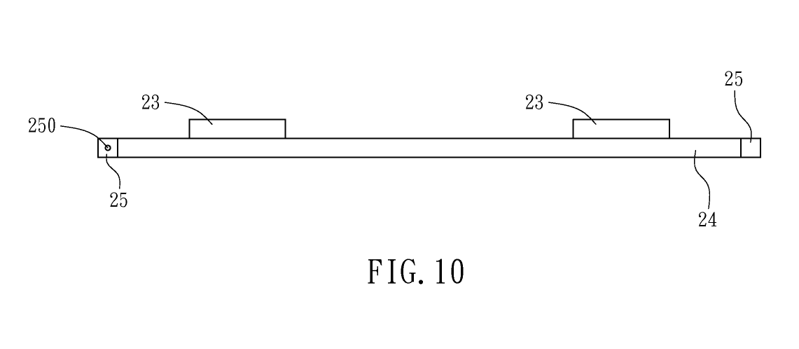

Please refer to FIG. 10, which is a C-C′ sectional view of FIG. 7. As shown in FIG. 10, there are two distributors 23 disposed on top of the shower 24 while the shower 24 has two cooling blocks 25 attached to the two sides thereof; and the two cooling water conduit formed inside the two cooling block 25 as elongated holes are used for allowing cooling water to flow in and out of the shower 24.

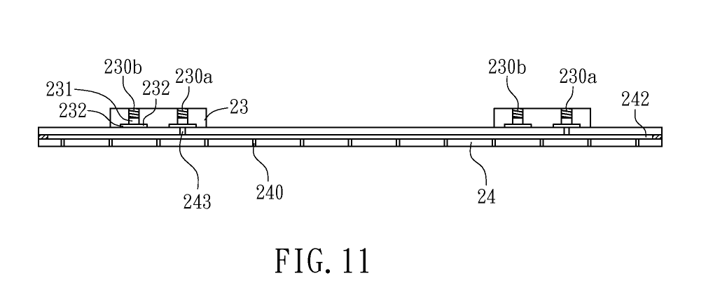

Please refer to FIG. 11, which is an A-A′ sectional view of FIG. 7 without showing the two cooling blocks. As shown in FIG. 11, each distributor 23 is formed with two inlets 230a and 230b to be used for allowing two different gases filled in different gas channels to flow into the two diffusion cells 231 of the distributor 23 in respective, by that the flow of the two different gases, i.e. the first gas and the second gas, can be buffered in the two diffusion cells 231 and thus spread therein. In addition, the shower 24 is formed with at least a shower channel 242 that each is connected to one of the diffusion cells 231 by gas-inlet passages 243 for allowing the gas in the corresponding diffusion cell 231 to flow into the shower channel 242 therethrough. Moreover, the shower channel 242 is further connected to gas-outlet passages 240 so that the gas in the shower channel 232 can be sprayed into the gas deposition chamber therethrough.

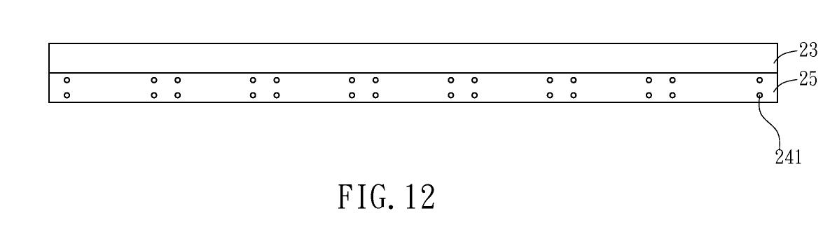

Please refer to FIG. 12, which is a D-D′ sectional view of FIG. 7. Since the two cooling blocks are attached to the two sides of the shower 24, the shower 24 is not visible in FIG. 12. As shown in FIG. 12, each cooling block 25 is fixed to the shower 24 by screwing screws n into the screw holes 241.

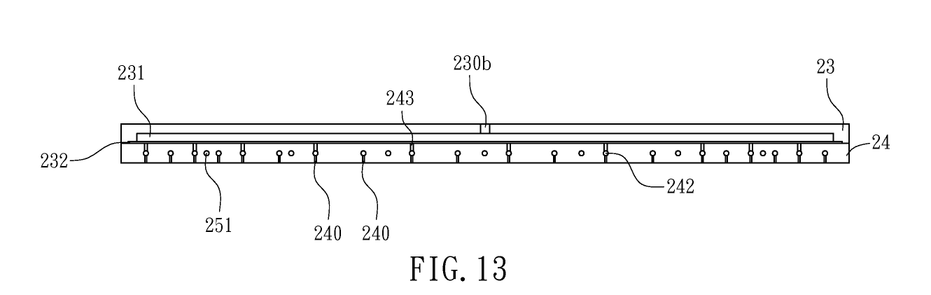

Please refer to FIG. 13, which is a B-B′ sectional view of FIG. 7. For distributing gas evenly, the distribution of the shower channels 242 is arranged in a dense-sparse-dense manner in FIG. 13. However, it can also be distributed in an equidistant manner. Moreover, the shower channels 242 are connected to the diffusion cells in an alternating manner that each shower channel 242 can allow only one gas to flow therein. In addition, the cooling passages 251 and the shower channels 242 are disposed parallel with each other in the shower 24.

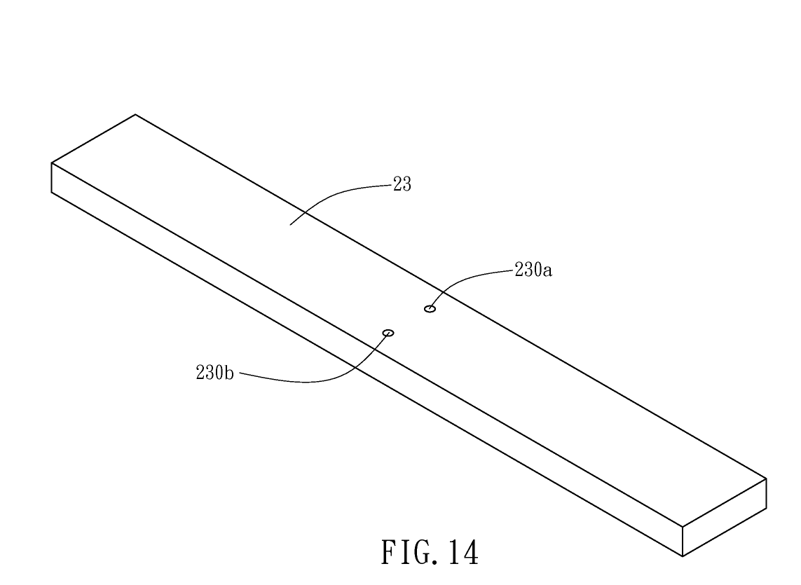

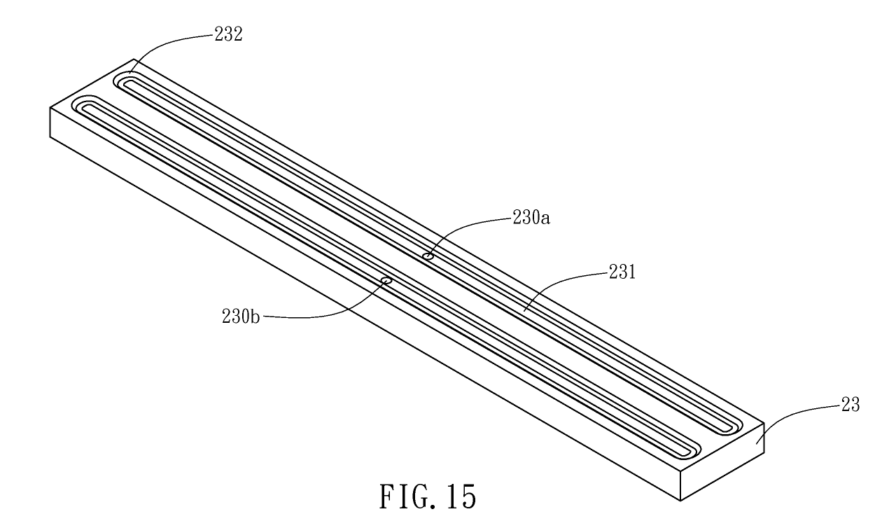

Please refer to FIG. 14 and FIG. 15, which are respectively a three-dimensional view of a distributor of the invention as it is viewed from the top thereof and a three-dimensional view of the same viewed from the bottom thereof. As shown in FIG. 15, there are sunken areas formed at one side of the distributor 23 to be used as diffusion cells 231, and for achieving airtight, the distributor 23 is formed with a groove 232 at a position surrounding the circumference of each diffusion cell 231 for receiving a sealing member like an 0-ring therein. It is noted that the side of the distributor 23 where the sunken areas are formed should be positioned facing toward the shower 24 for assembling the two.

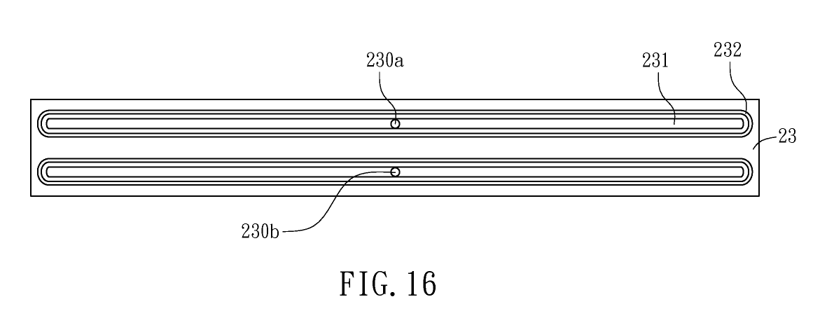

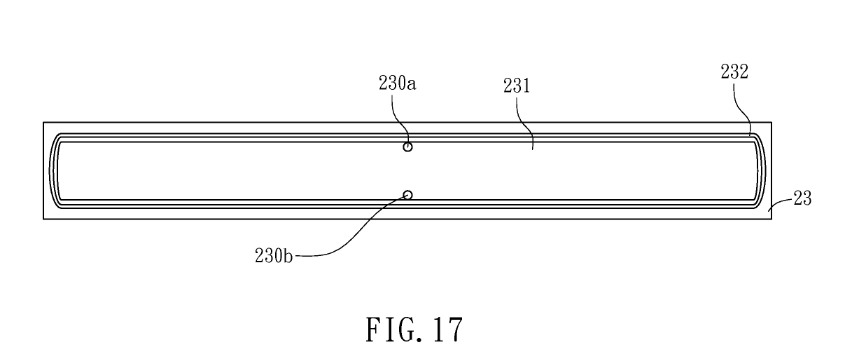

Please refer to FIG. 16 and FIG. 17, which are respectively the bottom views of two distributors according to different embodiments of the invention. In FIG. 16, there are two independent diffusion cells 231 formed on the distributor 23 in a manner that the two diffusion cells are surrounded by their corresponding grooves 232 and connected to their corresponding inlets 230a, 230b in respective for separating the two completely from each other. Thereby, the distributor of FIG. 16 is suitable for a coating process that requires gases to be prevented from mutually reacting before discharging. However, in the distributor 23 shown in FIG. 17, there is only a single diffusion cell 231 formed therein that is also surrounded by a groove 232 and connected to two inlets 230a, 230b. Therefore, it is suitable for a coating process that requires gases to be mutually reacting before discharging.

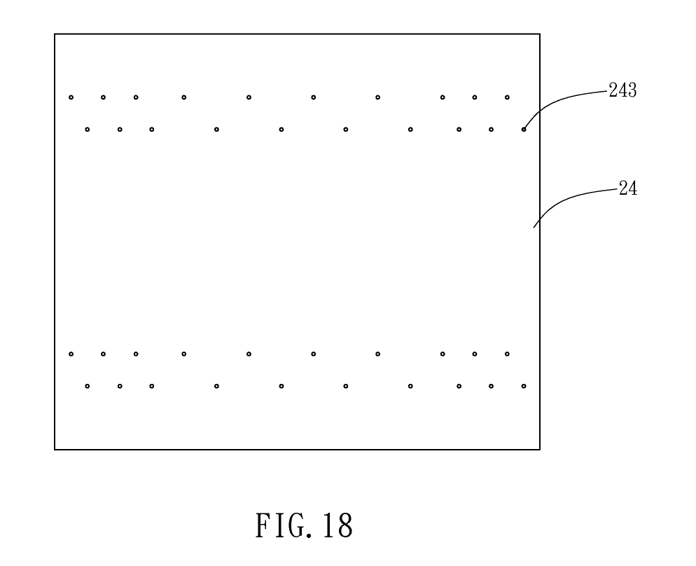

Please refer to FIG. 18, which is a top view of a shower of the invention. As shown in FIG. 18, the gas-inlet passages 243 are formed on the shower 24 at a side thereof facing toward the distributor 23 while enabling the same to be disposed alternatively at positions corresponding to the shower channel of the shower 24. It is noted that except for the alternating disposition as those shown in FIG. 18, the gas-inlet passages 243 can be distributed evenly.

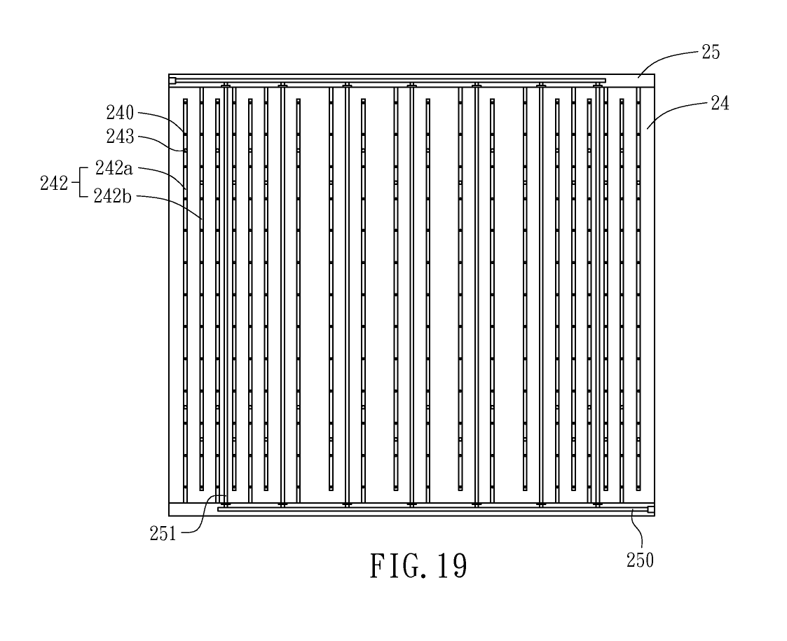

Please refer to FIG. 19, which is an X-ray view of a shower of the invention. In FIG. 19, the plural shower channels 242 can be formed inside the shower 24 by drilling as the shower 24 is generally a metal block. In this embodiment of FIG. 19, the shower channels 242a and 242b are grouped as one shower channel 242 for example. Thereafter, there are holes being formed on the shower channels 242 while enabling the holes relating to one side of the shower 24 to be used as the gas-inlet passages 243 and those relating to the opposite side of the shower 24 to be used as the gas-outlet passages 240. Moreover, for preventing the shower 24 itself from being coated and thus clogged by the gas flowing therein when the gas is overheated, there are cooling passages 251 formed inside the shower 24 for allowing a cooling water to flow therein. As there are two cooling block 25 attached to the two sides of the shower 24 and the cooling water conduits 251 of the two cooling blocks 25 are connected respectively to the two ends of each cooling passages 251, the cooling water is able to flow in and out the shower 24 for lower its temperature.

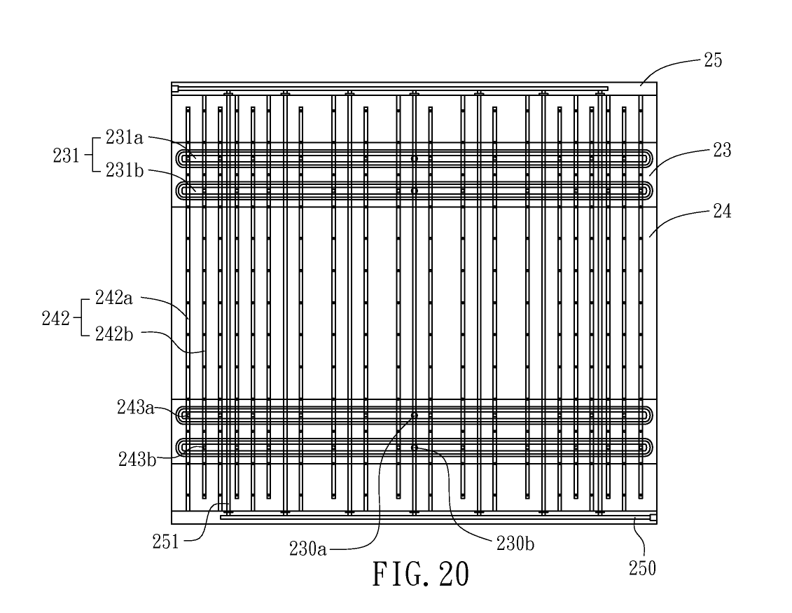

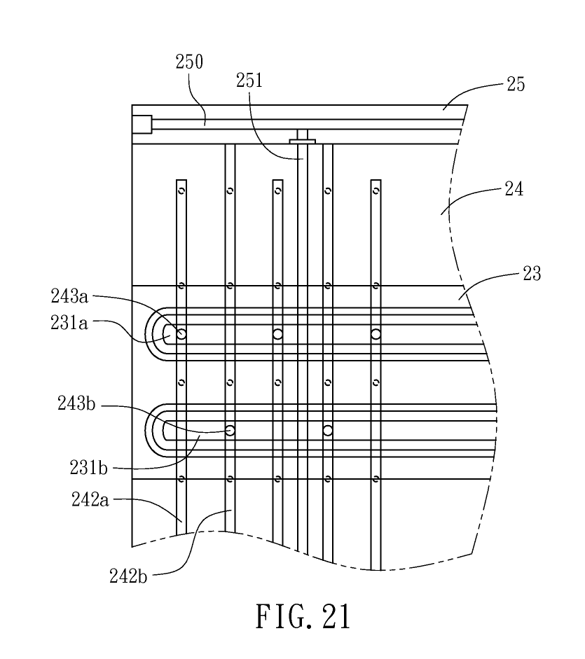

Please refer to FIG. 20 and FIG. 21, which are respectively an X-ray view of a gas shower module of the invention as the distributor and the shower are assembled, and is a partial enlarged view of FIG. 20. As shown in the figures, the exemplary shower channel 242a and shower channel 242b, being grouped as one shower channel 242, are connected respectively to the two diffusion cells 231a and 231b as the two diffusion cells 231a, 231b are filled with two mutually reactive different gases that should not be mixed before spraying. When the distributor 23 is assembled with the shower 24, the gas-inlet passages 243a will connected the diffusion cell 231 a to the shower channel 242a for allowing one of the two gases to flow into the shower channel 242a, and similarly, the gas-inlet passages 243b will connected the diffusion cell 231b to the shower channel 242b for allowing one of the two gases to flow into the shower channel 242b. Moreover, as the gas-inlet passages 243a and the gas-inlet passages 243b are alternatively disposed, such arrangement can facilitating the gases to be uniformly mixed after being sprayed. In addition, as the gases used in this embodiment are filled into their corresponding diffusion cells 231 of the distributor 23 in a first axial direction, and then they are guided to flow into the shower channel 242 of the shower 24 in a second axial direction, not only the gases can be distributed evenly on the whole planar surface for spraying, but also the gases can be separated from each other when they are flowing in the distributor 23 and the shower 24 but only can encounter with each other after being sprayed out of the shower 24. Although there are only two distributors 23 in this embodiment, there can be only one distributor 23, or more than three distributors 23 used in the gas shower module of the invention.

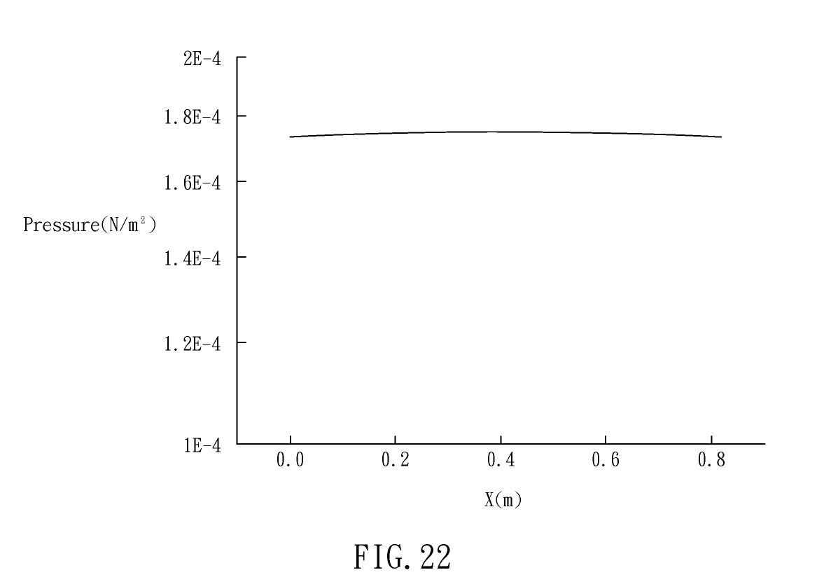

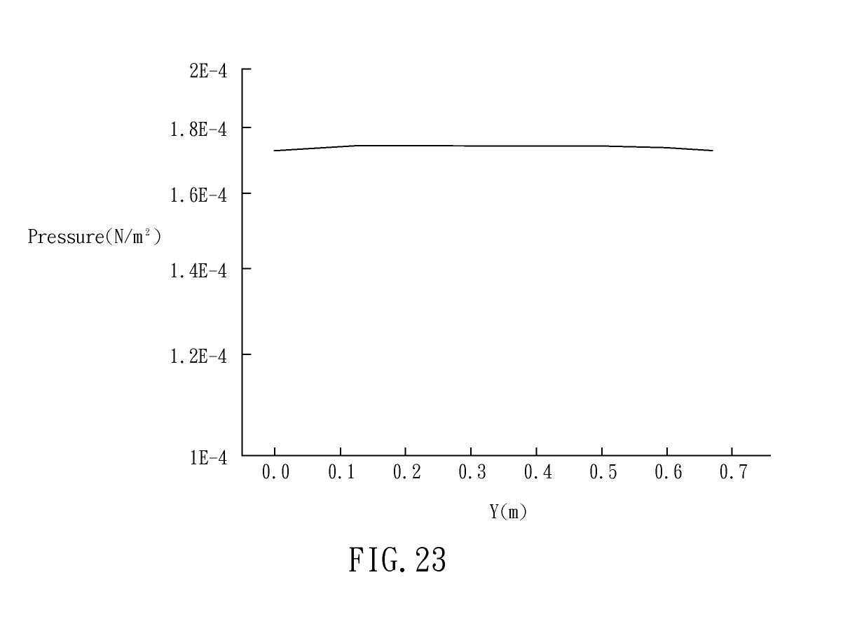

Please refer to FIG. 22 and FIG. 23, which are a X-directional pressure distribution diagram of a workpiece in a gas deposition chamber and a Y-directional pressure distribution diagram of the same. It is noted from the aforesaid FIG. 22 and FIG. 23 that the ratio between the maximum pressure and minimum pressure that are exerted on the substrate in the vapor deposition chamber by the gas shower module of the invention in both X direction and Y direction are about 1.02 with 2.3% error, indicating that the gas shower module of the invention is quite capable of distributing gas uniformly on the substrate.

In the embodiments of the invention, the axial direction, i.e. referred as the X direction, along the extending of the diffusion cell is perpendicular and orthogonal to the axial direction, i.e. referring as the Y direction, along the extending of the shower channel. However, it is not limited thereby and can be varied by users according to actual requirement. But they shall not be arranged against the following principle, that is, the extending axial direction of the diffusion cell is never parallel with the extending axial direction of the shower channel. Moreover, there can be more than one inlet being formed in the distributor 23 despite that there is only one inlet used in the embodiments of the invention. Taking the embodiment shown in FIG. 5 for instance, it is possible to guide a gas flowing in one gas channel to flow into more than two sub-channels simply by fitting a joint to the cap 32, and thereby, guide the gas to be filled into a same diffusion cell 231 through more than one inlets respectively connected to those sub-channels. Nevertheless, the amount of the diffusion cell is determined according to whether the gases used in a coating process should be mixed before spraying and also according to actual requirement of users. For example, there can be two inlets for one diffusion cell, or two inlets for two independent diffusion cells, and so on. It is noted that the gas shower module is also applicable for those coating process requiring the use of more than three different gases.

For preventing the gas to flow directly into the shower channel through the gas-inlet passages and then being also directly sprayed out of the same through the gas-outlet passages, the gas-inlet passages and the gas-outlet passages not disposed directly in correspondence to one another. Moreover, the diameter of each gas-outlet passages should be ranged between 0.1 centimeter and 2 centimeters.

In the embodiments of the invention, the cooling passages in the distributor are linear tubes that are disposed parallel with the shower channel. However, it is not limited thereby and thus can be disposed unparallel to the shower channel. One embodiment is by placing the cooling passage and the shower channel in a stacking manner so that the two can be disposed unparallel with each other. However, the stacking arrangement will result a thicker, heavier, larger distributor that not only it is not practical, but also is more costly in manufacture.

From the above description, it is noted that the gas shower module not only can mix and distribute gases evenly on the whole spraying surface, but also since it can be manufactured by common processing means of drill and mill, it is comparatively easy and cheap to manufacture as well as it is easy to assembled. In addition, if it is required to perform two different coating processes in one gas deposition chamber as one of the two processes requiring its gases to be separated for preventing mutually reacting before discharging and another process requiring its gases to be mutually reacting before spraying, such two different coating processes can be performed simply by changing the distributor in the gas shower module accordingly.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A gas shower module for gas deposition chamber with gas channel, comprising:
at least a distributor, further comprising:
at least one diffusion cell, configured therein along a first axial direction; and
a plurality of inlets, respectively connecting to the gas channel and the diffusion cell; and
a shower, further comprising:
at least one shower channel, configured therein along a second axial direction;
a plurality of gas-inlet passages, for connecting the at least one shower channel to the diffusion cell; and
a plurality of gas-outlet passages, for connecting the at least one shower channel to the gas deposition chamber;
wherein, the distributor and the shower are interconnected to each other for enabling the diffusion cell to communicate with the shower channel through the gas-inlet passages; and the first axial direction is not be parallel to the second axial direction.

2. The gas shower module of claim 1, wherein the distributor is formed with a groove at a position surrounding the circumference of the diffusion cell for receiving a sealing member therein.

3. The gas shower module of claim 2, wherein the sealing member is an O-ring.

4. The gas shower module of claim 1, wherein the gas-inlet passages and the gas-outlet passages not disposed in correspondence to one another.

5. The gas shower module of claim 1, wherein the distributor is further formed with at least a cooling passage therein.

6. The gas shower module of claim 5, further comprising:
two cool blocks, being disposed and attached to two sides of the shower, each provided for at least one cooling water conduit to be formed therein in a manner that the at least one cooling water conduit is connected to the cooling passage.

7. The gas shower module of claim 6, wherein the cooling water conduits formed inside the two cool blocks are provided in a manner that one of the two cooling water conduit is selected for allowing a cooling water to flow in therefrom while another water cooling conduit is used for allowing a cooling water to flow out.

8. The gas shower module of claim 5, wherein the at least one cooling passage and the at least one shower channel are alternatively disposed and parallel with each other.

9. The gas shower module of claim 7, wherein the at least one cooling passage and the at least one shower channel are coplanar disposed.

10. The gas shower module of claim 1, wherein there is an 0-ring sandwiched between the distributor and the shower and the distributor and the shower are integrated by screwing screws into corresponding screw holes.

11. The gas shower module of claim 1, wherein the first axial direction is orientated orthogonal to the second axial direction.

12. The gas shower module of claim 1, wherein each gas-outlet passage is shaped like a column with a diameter ranged between 0.1 centimeter and 2 centimeters.

13. The gas shower module of claim 1, wherein the distributor is formed with a first diffusion cell and a second diffusion cell while enabling the two diffusion cells to be orientated parallel with each other, and the shower is formed with a first shower channel and a second shower channel while enabling the two shower channels to be orientated parallel with each other and the same time enabling the first shower channel to be connected only to the first diffusion cell and the second shower channel to be connected only to the second diffusion cell.

14. The gas shower module of claim 13, wherein the distributor is formed with at least a plurality of gas-inlet passages and a plurality of second gas-inlet passages while enabling the first gas-inlet passages to be used for connecting the first diffusion cell to the first shower channel and the second gas-inlet passages to be used for connecting the second diffusion cell to the second shower channel; and the first gas-inlet passages and the second gas-inlet passages are alternatively disposed.

15. The gas shower module of claim 13, wherein the distributor is formed with a groove at a position surrounding the circumference of the first diffusion cell for receiving a sealing member therein.

16. The gas shower module of claim 13, wherein the distributor is formed with a groove at a position surrounding the circumference of the second diffusion cell for receiving a sealing member therein.

17. The gas shower module of claim 14, wherein the first gas-inlet passages and the gas-outlet passages not disposed in correspondence to one another.

18. The gas shower module of claim 14, wherein the second gas-inlet passages and the gas-outlet passages not disposed in correspondence to one another.

19. The gas shower module of claim 14, wherein the plural first gas-inlet passages formed in the distributor are connected to the first diffusion cell.

20. The gas shower module of claim 14, wherein the plural second gas-inlet passages formed in the distributor are connected to the second diffusion cell.

21. The gas shower module of claim 6, wherein there is an O-ring formed surrounding the cooling passage for sealing the integration of the corresponding cool block and the distributor.

22. The gas shower module of claim 21, wherein the cooling passage is orientated parallel to the second axial direction.

23. The gas shower module of claim 19, wherein the cooling passage and the shower channel are coplanar disposed.

24. The gas shower module of claim 21, wherein the cooling passage is substantially an elongated hole.

25. The gas shower module of claim 22, wherein the cooling passage is substantially an elongated hole.

26. The gas shower module of claim 23, wherein the cooling passage is substantially an elongated hole.

27. The gas shower module of claim 13, wherein the shower channel is composed of a plurality of elongated holes.

28. The gas shower module of claim 13, wherein there are two distributors disposed at the two top corners of the shower.

29. The gas shower module of claim 28, wherein there is yet another distributor to be placed at a position between the aforesaid two distributor.

30. The gas shower module of claim 1, wherein each distributor is formed with more than one inlet holes.
